(19) United States
(12) Patent Application Publication
(10) Pub. No.: US 2008/0110668 A1
(43) Pub. Date: May 15, 2008

(54) Telecommunication connector PCB layout

(76) Inventor: Yu Cheng Lin, Yang Mei Chen (TW)

Correspondence Address: NATH & ASSOCIATES PLLC, 112 South West Street, Alexandria, VA, 22314, US

(21) Appl. No.: 11/594,877

(22) Filed: Nov. 9, 2006

(51) Int. Cl. H05K 3/00; H05K 1/00

(52) U.S. Cl. 174/258; 174/250; 29/829

(57) ABSTRACT

The preferred embodiment the invention proposes pertains to a Telecommunication connector PCB layout, which is primarily comprised of the components of a fiberglass board or other condensed board material, copper foil, position hole, through hole. The invention utilizes the inner layer board for main circuit layout that allows the response circuit gap to instantly achieve an optimal balancing power condensing effect at the nearest distance, and the circuit will not be hindered by the outer layer's pressure resistance issue or the circuit's multiple copper buildups, and is able to derive a maximum compensation to the response yield at where near the plug to be able to better achieve stabilizing the functions of category-six communications protocols.

### FIELD OF THE INVENTION

The preferred embodiment the invention proposes pertains to a telecommunication connector Printed Circuit Board (PCB) layout, which is primarily comprised of the components of a fiberglass board or other condensed board material, copper foil, position hole, through hole.

### BACKGROUND OF THE INVENTION

The conventional layout of a double-layer board or a multiple-layer board tends to place the main leads on the outer layer. When the outer layer's non-circuit portion are dissolved in etching liquid, the circuit portion of the leads are preserved from being dissolved by the etching liquid. Through holes, which provide electrical connections between the circuits on the top and bottom surfaces of a PCB layer, need to undergo a primary and secondary copper plating, which deposits the through hole with copper buildup.

As a result, the circuit portion of the leads tend to be subjected to a multiple number of copper buildups, where each procedure can exceed one more PCB tolerances. This results in the inability to control the lead width, line distance and copper thickness tolerance, aggregating the line width, line distance and copper thickness dimensional tolerance. It also leads to unstable compensation effect. Suppose when a negative compensation of power condensing or power inducting effect is added to the outer layer copper foil to derive a larger amount and more concentrated response, the circuit would need to be packed tightly. This tends to cause crystallization, to lead to bridge short-circuiting, and to lead to insufficient voltage resistance, all also hampering the fabrication process.

### SUMMARY OF THE INVENTION

The invention pertains to a telecommunication connector PCB layout and a PCB in which the main circuit is located on an inner layer board of a multilayer board, and a small number of circuits are located on the most outer layer. In this way a negative compensation can be made to the inner layer board, where the interference is deemed the largest, through a condensing circuit. Also, the response circuit gap can be at the etching threshold of under 0.15 mm and thereby derive a greater response compensation, and achieve a stabilization of the circuit. This satisfies the concern of underrated voltage resistance and maintains also the stability of board thickness.

When the invention is applied in signal transmission, the response circuit gap on the main leads of an inner layer board of a multilayered circuit board is kept to a small distance. This is for canceling a response concentration at a maximum yield and can result in a more stabilized result. It can also achieve optimal functioning of a telecommunication connector PCB layout and improve the quality of high-frequency signal transmission. It can also enhance the accuracy in signal transmission, thus improving the product's overall operating yield.

A circuit placed on the outermost layer of a double-layer circuit board tends to result in an unstable compensation effect caused by the aforementioned effect and resulting in a large disruption rating. This leads to difficulty in controlling the precision response tolerance required of category-six communications protocols, and leads to unstable functioning. Also, the smallest distance between the leads on the outer layer board can only be 0.2 mm in order to ensure that there is a 1000 VAC voltage resistance. However, if the nearest distance between the leads of a response circuit is kept over 0.2 mm, the circuit compensation or density will not be able to achieve a voluminous and concentrated effect.

The invention pertains to incorporating an internal wire circuit and response circuit layout on the top and bottom of a cooper foiled or clad substrate. With the invention's response circuit at the inner layer board, which is covered by the outer layer board, the responses leads, when placed in close proximity, will not cause insufficient voltage resistance, and that the inner layer only requires undergoing one etching to derive a higher precision. The inner layer circuit board's not needing to undergo an initial and secondary copper plating, and the response circuit's gap between wires can be kept to the etching threshold of below 0.15 mm at the closest distance produces a maximum compensation stabilizing value. They result in a large concentration of offsetting effect to achieve the functions of category-six communications protocol.

In a specific embodiment of the invention, an inner layer board is utilized for a main circuit layout that allows the response circuit gap to instantly achieve an optimal balancing power condensing effect at the nearest distance.

### BRIEF DESCRIPTION OF THE DRAWINGS

FIG. 1 is a top view of a circuit placed on the most outer layer of a multiple-layer board that can be used as part of a PCB for a telecommunication connector in accordance with the present invention;

FIG. 2 is a top view of a circuit placed on the inner layer of a multiple-layer board in accordance with the present invention;

FIG. 3 is a bottom view of a circuit placed on an inner layer of a multiple-layer board in accordance with the present invention;

FIG. 4 is a bottom view of a circuit placed on the most outer layer of a multiple-layer board in accordance with the present invention;

FIG. 5 is a sectional view of a multiple-layer board in accordance with the present invention; and

FIG. 6 is an exploded perspective view of a telecommunications connector showing the connector housing and a PCB and connector leads to the PCB that are are mounted in the housing.

### DESCRIPTION OF THE PREFERRED EMBODIMENT

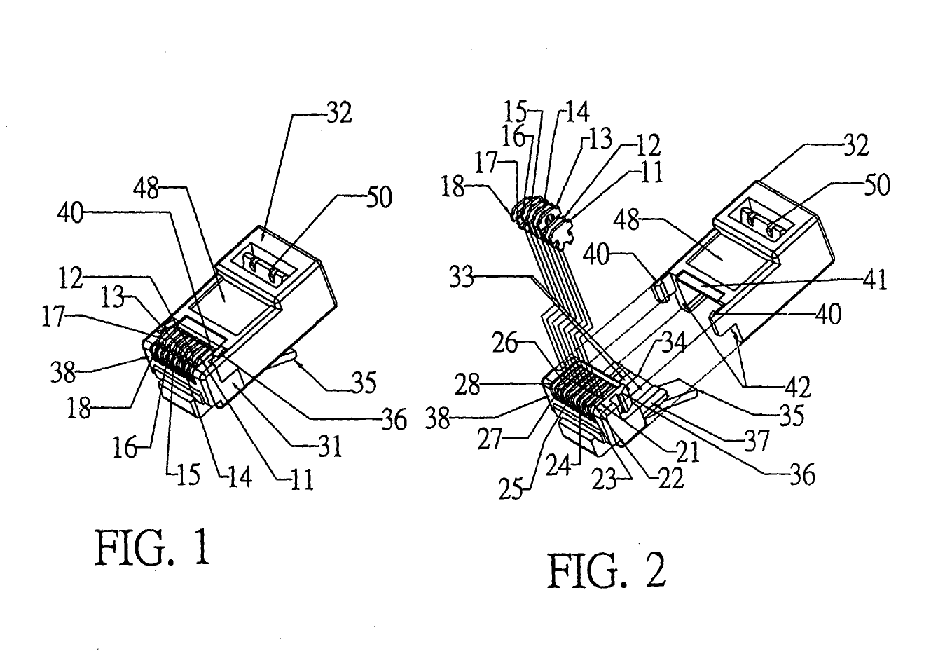

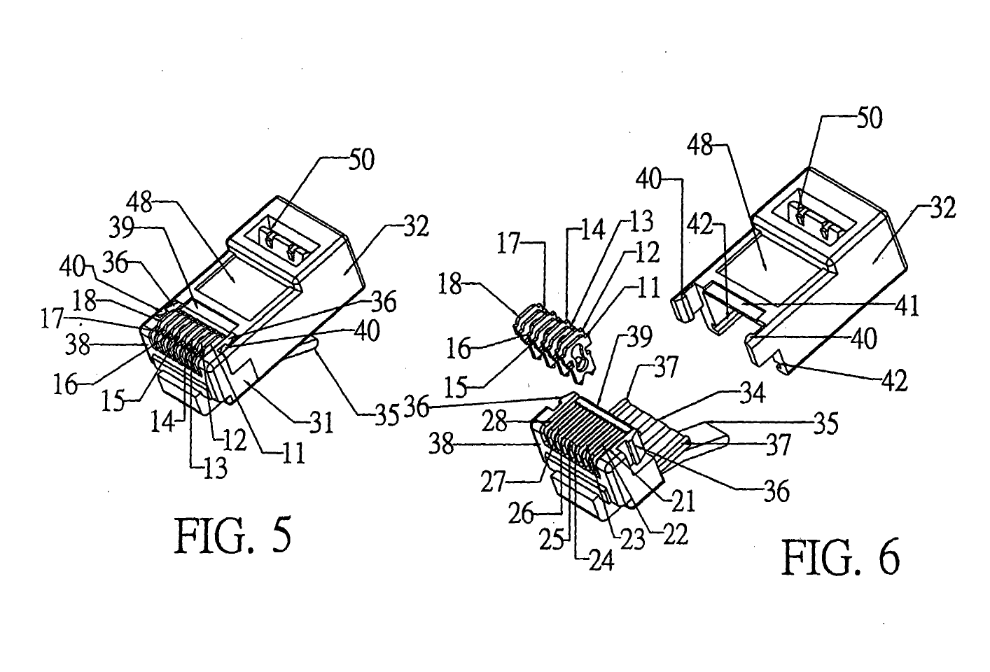

With reference to the drawings, and particularly FIGS. 1, 3 and 5, an embodiment of the present invention is depicted. A multilayered printed circuit board includes a substrate 11 comprised of a board 12 made of fiberglass or other condensed board material and a cladding of a cooper foil 13 on each side. A top outer circuit board and a bottom outer circuit board are each comprised of an outermost copper foil layer 13 clad on a supporting top outer board and a bottom outer board 12. The main circuit layout is formed on the top and bottom of cooper foil substrate 11.

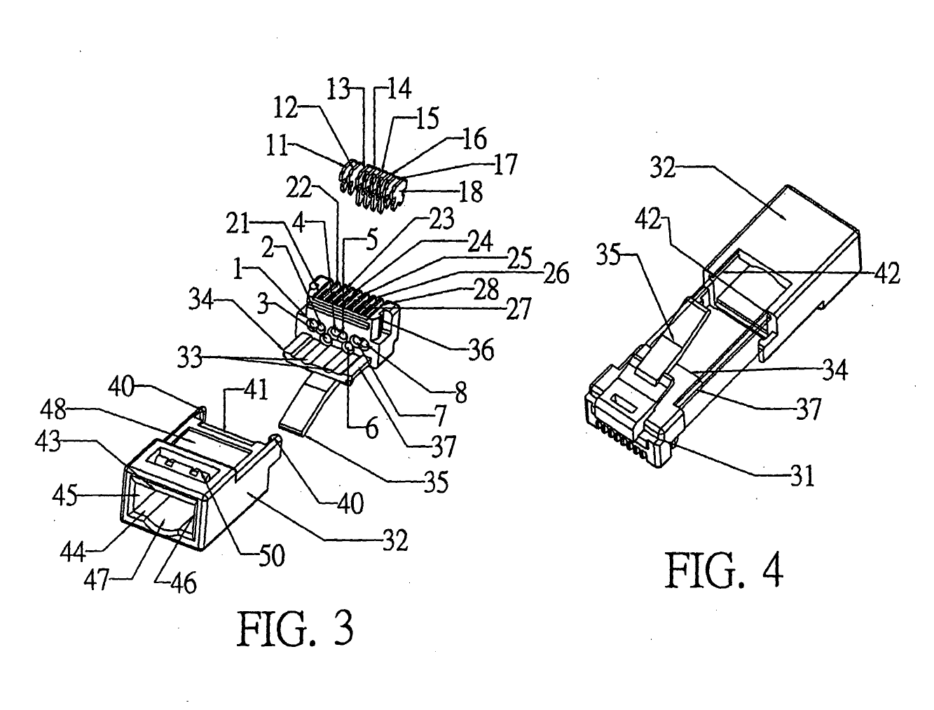

While as the inner layer board 15's non-circuit portion 6 needs to be dissolved in etching liquid, the circuit portion 7 of the leads are retained for being protected without being dissolved by an etching liquid. Each board has at least one positioning hole 3, and a plurality of through holes 1. External connection points 5 are located on the top outer board (FIG. 1) and the bottom outer board (FIG. 3) and are spaced apart the requisite distance to comply with the protocols.

As the copper foil 13 becomes the top and bottom of the most inner layer board 15 (FIG. 2 and 3) once dissolved by the etching liquid, fiberglass substrate or other condensed material are sequentially placed and bonded on the top and bottom of cooper foil substrate 11, and the required line layout is formed on the copper foil before it is dissolved through etching. Through the sequent, a multi layer inner layer board 15 is formed, and at last, the fiberglass board or other condensed board material 12 and copper foil 13 are placed on the top and bottom and bonded together to form the most outer layer board 16 (FIG. 1 and 4).

The main response circuit 2 of the multi layer board formed are contained in the inner layer board 15, and at least a small number of lines can be placed on the most outer board 16, where the cooper foil is dissolved using the etching liquid and a small number of lines are retained, and that the multiple layer board is drilled with a through hole 1 and position hole 3, where the through hole I undergoes primary and secondary copper plating (5) for deposit cooper in the through hole 1. Therefore, the response 2 on the inner layer board 15 that is covered by the outer layer board 16 will not cause insufficient voltage resistance.

The invention has the main circuit and effect circuit placed on the inner layer board and a small portion of the circuit on the most outer layer board 16, with the inner layer board 15 requiring only one etching to offer a higher precision, where the stability of the board thickness without incorporating power condensing effect between different layers will keep from interfering the compensation value, and that response circuit 2 gap can be kept to below the etching threshold of under 0.15 mm to derive a maximum response rating in completion.

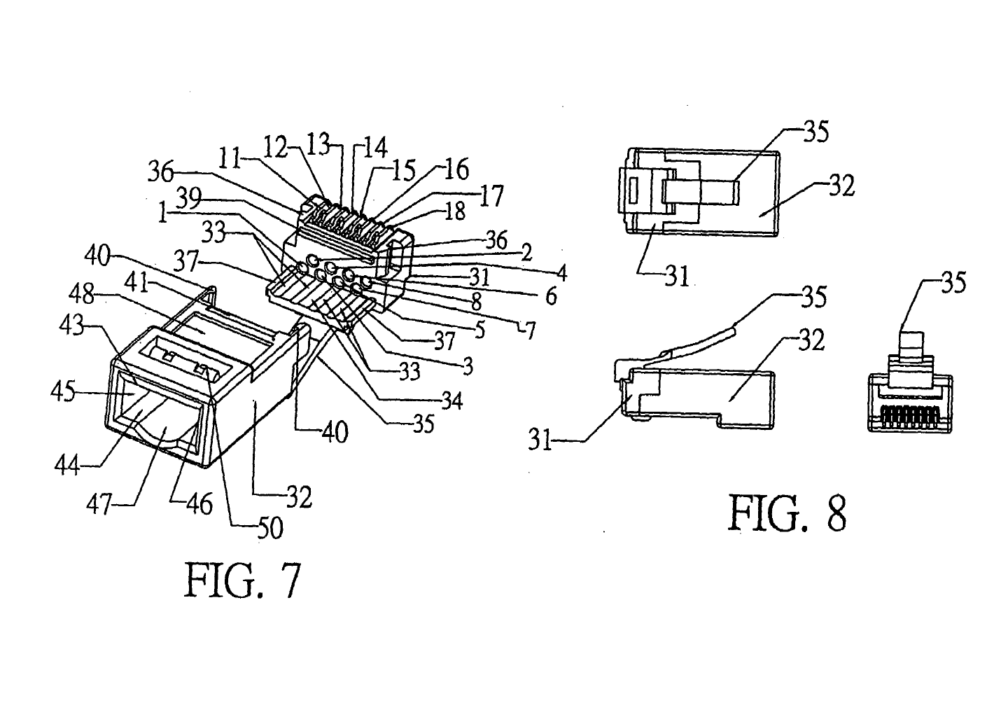

With reference to FIG. 6, a telecommunication connector 26 is comprised of a printed circuit board 21 and a category-three grade's front contact terminal 22. It makes the required precision effective tolerance easier to maintain for achieving functional stability, also allows the entire information jack to comply with and exceed the functions of category-six communications protocols.

As can be revealed from the cross-talk figures derived from adopting the invention in a high-frequency connector as analyzed through a high-frequency networking analyzer, when first pair and second pair's leads are at 250 MHz, the close-range cross-talk rating is at 57.63 dB; when at 200 MHz frequency, the close-range cross-talk rating is at 77.33 dB; when at 100 MHz frequency, the close-range cross-talk rating is at 58.86 dB. When pair one and pair three's leads are at 250 MHz frequency, the close-range cross-talk rating is at 47.47 dB; when at 200 MHz frequency the close-range cross-talk rating is at 55.33 dB; when at 100 MHz frequency, the close-range cross-talk rating is at 59.52 dB. When pair one and pair four's leads are at 250 MHz frequency, the close-range cross-talk rating is at 55.91 dB; when at 200 MHz frequency, the close-range cross-talk frequency is at 59.81 dB; when at 100 MHz frequency, the close-range cross-talk rating is at 71.12 dB. When pair two and pair three's leads are at 250 MHz, the close-range cross-talk rating is at 48.43 dB; when at 200 MHz, the close-range cross-talk frequency is at 50.26 dB; when at 100 MHz frequency, the close-range cross-talk rating is at 64.61 dB; when at 100 MHz frequency, the close-range cross-talk frequency is at 71.62 dB. When pair three and pair four's leads are at 250 MHz frequency, the close-range cross-talk rating is at 51.5 dB; when at 200 MHz frequency, the close-range cross-talk rating is at 55.52 dB; when at 100 MHz frequency, the close-range cross-talk rating is at 65.06 dB. When compared with the above figures to the close-range cross-talk ratings set by category-six communications protocols, in the close-range cross-talk category-six table, the close-range cross-talk rating is at 46 dB at 250 MHz, and at 48 dB at 200 MHz, and at 54 dB at 100 MHz, which reveal that the experiment figures tested by applying the invention on a high-frequency connector have indeed surpassed category six close-range cross-talk criteria.

Of the actual return-loss figures derived from applying the invention in a high-frequency connector, when pair two's leads are at 250 MHz frequency, the close-range cross-talk rating is at 22.8 dB; when at 200 MHz frequency, the close-range cross-talk rating is at 26.07 dB; when at 100 MHz frequency, the close-range cross-talk rating is at 34.14 dB. When pair three's leads are at 250 MHz frequency, the close-range cross-talk rating is at 32.64 dB; when at 200 MHz frequency, the close-range cross-talk rating is at 38.43 dB; when at 100 MHz frequency, the close-range cross-talk rating is at 37.55 dB. When pair one's leads are at 250 MHz frequency, the close-range cross-talk rating is at 21.78 dB; when at 200 MHz frequency, the close-range cross-talk rating is at 24.19 dB; when at 100 MHz frequency, the close-range cross-talk rating is at 36.05 dB. When pair four's leads are at 250 MHz frequency, the close-range cross-talk rating is at 22.73 dB; when at 200 MHz frequency, the close-range cross-talk rating is at 25.96 dB; when at 100 MHz frequency, the close-range cross-talk rating is at 34.93 dB, which indicate that the experiment figures on return loss tested through applying the invention to a high-frequency connector have indeed surpassed category six return loss criteria, validating that the invention can effectively reduce cross-talk interference, and improve the quality of high frequency signal transmission.

The invention's information jack circuit layout pertains to having the main circuit placed on the inner layer board 15, and a small portion of circuit is placed on the outer most layer board 16, allowing the main circuit's response leads 2 to achieve an optimal power condensing effect to be more balanced in close range, without being affected by impurity, dust, or static, and also to excel PCB's cross-talk compensation with a higher function.

I claim:

1. A multiple layered telecommunication connector PCB layout includes a topmost board comprised of an upper copper clad layer on a topmost substrate, an inner board comprised of an inner board clad on the upper side thereof with a first, copper clad layer and clad on the bottom side thereof with a second, copper clad layer, and a bottom most board comprised of a lower copper clad layer on a bottom most substrate;
at least one position hole through said topmost, inner and lower most boards; and
a through hole through said topmost, inner and lower most boards;
said inner top and inner bottom copper foil substrate contain the main circuit and effect circuit layout, and
said top most board and said bottom most boards contain the input and output terminals.

2. A telecommunication connector PCB Layout as claimed in claim 1, wherein the condensed board material is selected among the group consisting of insulating paper phenol substrate, FR 4 fiberglass board and fiberglass epoxy.

3. A telecommunication connector PCB Layout as claimed in claim 1, wherein the multiple layered board formed has the main effect circuit located on the inner layer board, and a small portion of the circuit is located on the outer most layer.

4. A telecommunication connector PCB Layout as recited in claim 3, wherein an effect circuit gap of said inner layer board is under 0.15 mm.

5. A Telecommunication Connector PCB Layout as recited in claim 1, wherein the through hole has copper deposit at the hole.

6. A Telecommunication Connector PCB Layout as recited in claim 1, wherein the inner layer board has undergone only one etching.

7. A method of making a telecommunications connector PCB comprising the steps of
providing an inner board comprised of a substrate clad with an upper cladding of copper and a lower cladding of copper,
producing a line circuit on each of said upper and lower cladding in which the inner layer board's line circuit has been protected and a non circuit portion is dissolved through etching liquid, and the line circuit that has been protected will be preserved without being dissolved by etching liquid;
laying a copper cladding on the top and bottom of an outer upper board and an outer lower board;
outlining a circuit on said outer copper cladding and dissolving where the copper foil has been etch dissolved with a small portion of lines retained, which has a circuit layout made by partial etching dissolution,
bonding said inner and two outer boards together to form a multiple layered inner board; and
locating a top and bottom board with each other to form the most outer layer, and the multiple layer board and drilling them with a through hole and position hole.

8. A method as claimed in claim 7 wherein the inner layer board has undergone only one etching.
